(19) United States
(12) Patent Application Publication
(10) Pub. No.: US 2026/0190545 A1
(43) Pub. Date: Jul. 2, 2026

(54) LIGHT EMITTING DEVICE

(71) Applicant: SEOUL VIOSYS CO., LTD., Ansan-si (KR)

(72) Inventor: Hongjae YOO, Ansan-si (KR)

(73) Assignee: SEOUL VIOSYS CO., LTD., Ansan-si (KR)

(21) Appl. No.: 19/434,483

(22) Filed: Dec. 29, 2025

Related U.S. Application Data
(60) Provisional application No. 63/740,383, filed on Dec. 31, 2024.

(51) Int. Cl. H10H 20/816; H10H 20/821

(52) U.S. Cl. CPC H10H 20/8162; H10H 20/821

(57) ABSTRACT

A light emitting device includes a first semiconductor layer doped with a first dopant, a blocking layer disposed on the first semiconductor layer, an active layer disposed on the blocking layer, and a second semiconductor layer disposed on the active layer and doped with a second dopant. The blocking layer may include indium. The blocking layer and the active layer may include a flat region and an approach region. The approach region may include a slope region. In addition, the approach region may include first slopes and second slopes facing each other, and may include intersections where the first slopes and the second slopes meet. The intersections may include a first intersection that is disposed farthest from the first semiconductor layer and a second intersection that is disposed closest to the first semiconductor layer.

### CROSS-REFERENCE TO RELATED APPLICATIONS

The present application claims the benefit of priority to U.S. Provisional Application No. 63/740,383, filed Dec. 31, 2024, the entire contents of which are incorporated herein by reference.

### TECHNICAL FIELD

The present invention relates to a light emitting device.

### BACKGROUND

In general, nitrides of Group III elements such as gallium nitride (GaN) and aluminum nitride (AlN) have excellent thermal stability and a direct transition type band structure, and thus have been attracting considerable attention as materials for light emitting diodes.

Light emitting diodes employing compound semiconductors of gallium-nitride family are utilized in various applications, including large-scale display devices, backlight sources, traffic lights, indoor lighting, optical communications, or others.

However, in consideration of economic feasibility and other factors, a heterogeneous substrate such as a sapphire substrate is often used for growing a nitride semiconductor layer. When a nitride semiconductor layer grown on such a heterogeneous substrate, strain may occur due to a lattice-constant mismatch between the substrate and the growth layer, which may in turn lead to crystalline defects.

### SUMMARY

A problem to be solved by the present invention is to improve the light-emitting efficiency of a light emitting device by reducing non-radiative recombination.

Another problem to be solved by the present invention is to prevent a reduction in the light output of a light emitting device caused by threading dislocations, by adjusting a size of an approach region.

Another problem to be solved by the present invention is to improve the light uniformity of a light emitting device by scattering light emitted from an approach region of an active layer.

According to an embodiment of the present invention, a light emitting device is provided, including a first semiconductor layer doped with a first dopant, a blocking layer disposed on the first semiconductor layer, an active layer disposed on the blocking layer, and a second semiconductor layer disposed on the active layer and doped with a second dopant. The blocking layer may include indium. The blocking layer and the active layer may include a flat region and an approach region. The approach region may include a slope region. In addition, the approach region may include first slopes and second slopes facing each other, and may include intersections where the first slopes and the second slopes meet. The intersections may include a first intersection that is disposed farthest from the first semiconductor layer and a second intersection that is disposed closest to the first semiconductor layer. A straight line passing through the first intersection and the second intersection may be spaced apart from intersections disposed between the first intersection and the second intersection.

The straight line passing through the first intersection and the second intersection may be inclined with respect to the flat region.

A lower end of the approach region may be positioned in a partial region of the first semiconductor layer.

An indium content of the blocking layer may be equal to or lower than that of the active layer, and may be higher than that of the first semiconductor layer.

The blocking layer may include a first blocking layer disposed on the first semiconductor layer and a second blocking layer disposed on the first blocking layer.

The blocking layer may be provided with a plurality of the second blocking layers.

An indium content of the first blocking layer may be equal to or lower than that of the active layer, and an indium content of the second blocking layer may be lower than that of the first blocking layer.

A region between the first slope and the second slope forming the first intersection of the approach region may be symmetrical on both sides with respect to the straight line passing through the first intersection and the second intersection.

The region between the first slope and the second slope forming the first intersection of the approach region may be asymmetrical on both sides with respect to the straight line passing through the first intersection and the second intersection.

One of the first dopant and the second dopant may be an n-type dopant, and the other dopant may be a p-type dopant.

According to another embodiment of the present invention, a light emitting device is provided, including a first semiconductor layer doped with a first dopant, a blocking layer disposed on the first semiconductor layer, an active layer disposed on the blocking layer, and a second semiconductor layer disposed on the active layer and doped with a second dopant. The blocking layer may include indium. The blocking layer and the active layer may include an approach region having slope surfaces and a flat region. The approach region may include first slopes and second slopes facing each other. In addition, a scattering line may be formed in an inner region which is a region between the first slopes and second slopes.

The scattering line may have a structure in which at least one region is curved.

The first slope and the second slope of the active layer may have a plurality of inclination angles with respect to the scattering line.

A maximum separation distance between the first slopes and the second slopes of the approach region may vary along a thickness direction.

An indium content of the blocking layer may be equal to or lower than that of the active layer, and may be higher than that of the first semiconductor layer.

The blocking layer may include a first blocking layer disposed on the first semiconductor layer and a second blocking layer disposed on the first blocking layer.

An indium content of the first blocking layer may be equal to or lower than that of the active layer, and an indium content of the second blocking layer may be lower than that of the first blocking layer.

The intersections of the approach region may include a first intersection that is positioned farthest from the first semiconductor layer and a second intersection that is positioned closest to the first semiconductor layer. In addition, a region between the first slope and the second slope forming the first intersection may include a first inner region formed on one side and a second inner region formed on the opposite side, which are asymmetrical with respect to a straight line passing through the first intersection and the second intersection. A longer portion of the total lengths of the scattering line may be located in a wider one of the first inner region and the second inner region.

A light emitting device according to an embodiment of the present invention may improve the light-emitting efficiency by preventing dopants from moving into an active layer and reducing non-radiative recombination in the active layer.

A light emitting device according to an embodiment of the present invention may improve luminous efficiency by preventing a reduction in the light output of the light emitting device caused by threading dislocations, by adjusting a size of an approach region.

A light emitting device according to an embodiment of the present invention may improve the light uniformity of the light emitting device by scattering light emitted from an approach region of an active layer.

### BRIEF DESCRIPTION OF THE DRAWINGS

FIG. 1 is a cross-sectional view schematically illustrating one region of a light emitting device according to a first embodiment of the present invention.

FIG. 2 is an enlarged view of region A of FIG. 1.

FIG. 3 is a graph showing component composition contents of some regions of the light emitting device of FIG. 1.

FIG. 4 is a cross-sectional view schematically illustrating one region of a light emitting device according to a second embodiment of the present invention.

FIG. 5 is an enlarged view of region B of FIG. 4.

FIG. 6 is a cross-sectional view schematically illustrating one region of a light emitting device according to a third embodiment of the present invention.

FIG. 7 is an enlarged view of region C of FIG. 6.

FIG. 8 is a cross-sectional view schematically illustrating one region of a light emitting device according to a fourth embodiment of the present invention.

FIG. 9 is a schematic cross-sectional view of a light emitting package according to an embodiment of the present invention.

### DETAILED DESCRIPTION

In the following description, for the purposes of explanation, numerous specific details are set forth in order to provide a thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting device according to an embodiment of the present invention will be described in detail with reference to the accompanying drawings.

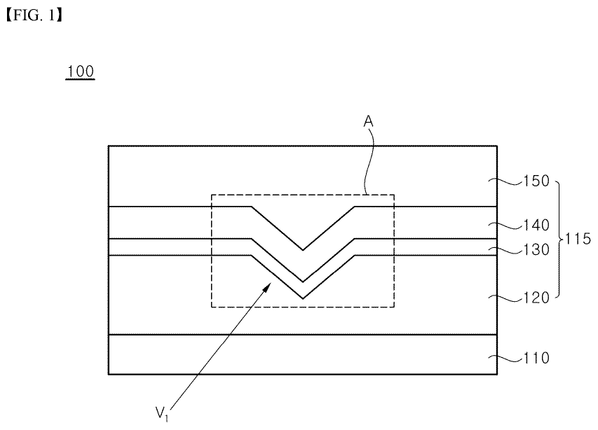

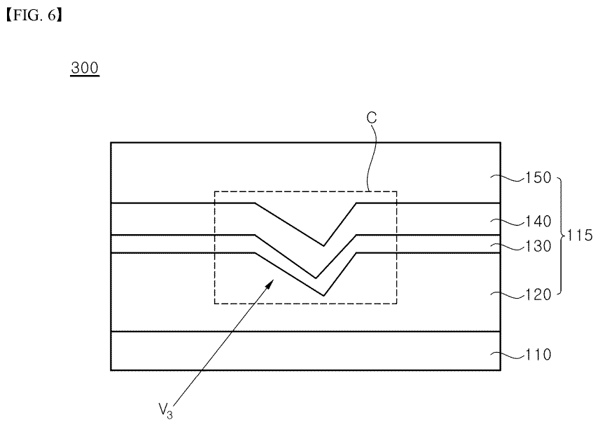

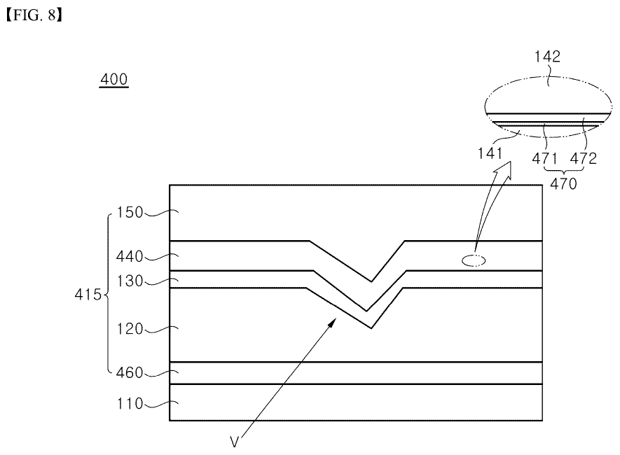

FIG. 1, FIG. 4, FIG. 6, and FIG. 8 are diagrams illustrating various embodiments of a light emitting device of the present invention. FIGS. 1, 4, 6, and 8 schematically illustrate only some regions of light emitting devices according to each embodiment. However, internal configurations of the light emitting devices according to the embodiments of the present invention are not limited to configurations shown in the drawings, and may further include other well-known internal structures such as electrodes and insulation layers.

FIGS. 1 to 3 are diagrams illustrating a light emitting device according to a first embodiment of the present invention.

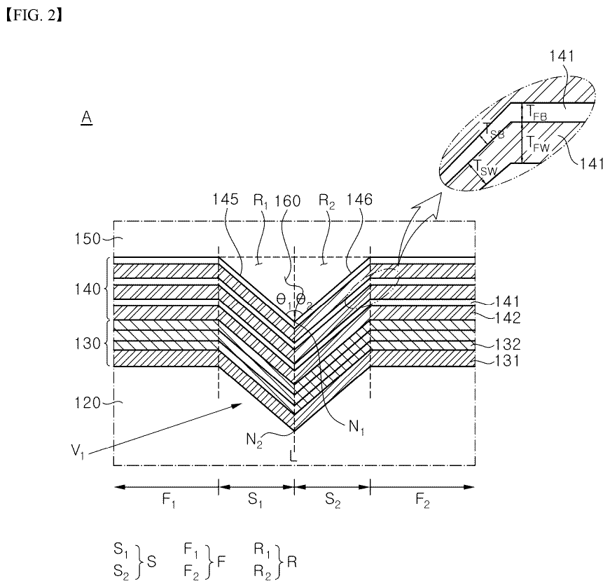

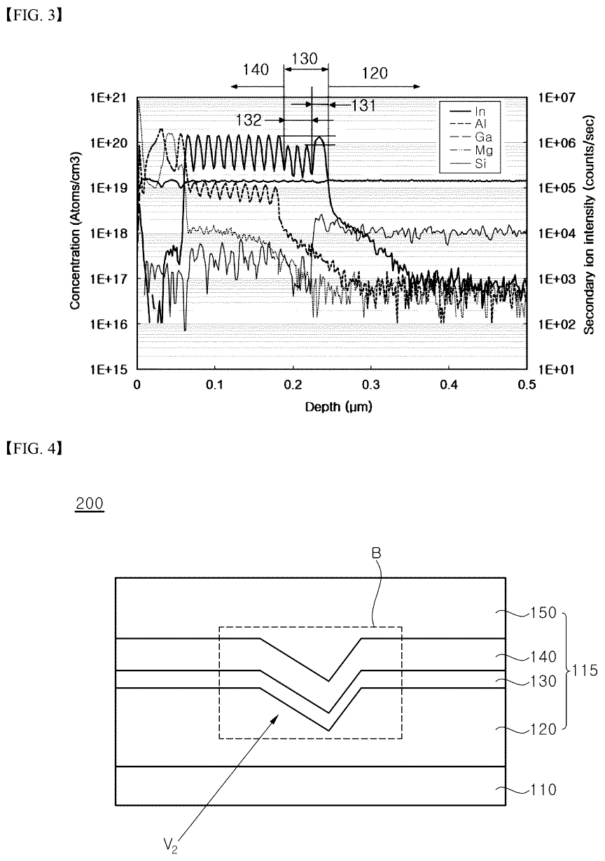

FIG. 1 is a cross-sectional view schematically illustrating one region of the light emitting device according to the first embodiment of the present invention. FIG. 2 is an enlarged view of region A of FIG. 1. In addition, FIG. 3 is a graph showing the compositional profile of certain regions of the light emitting device of FIG. 1.

Referring to FIG. 1, a light emitting device 100 according to the first embodiment may include a substrate 110 and a semiconductor layer 115. In addition, the semiconductor layer 115 may include a first semiconductor layer 120, a blocking layer 130, an active layer 140, and a second semiconductor layer 150.

The substrate 110 may be configured in various forms as a substrate for growing a semiconductor layer 115. For example, the substrate 110 may be one of a sapphire (Al₂O₃) substrate, a silicon carbide (SiC) substrate, a gallium arsenide (GaAs) substrate, a gallium nitride (GaN) substrate, a zinc oxide (ZnO) substrate, a silicon (Si) substrate, a gallium phosphide (GaP) substrate, an indium phosphide (InP) substrate, an aluminum nitride (AlN) substrate, and a germanium (Ge) substrate. In FIG. 1, the light emitting device 100 includes the substrate 110, but the substrate 110 may be removed after the semiconductor layer 115 is formed.

The first semiconductor layer 120 may be disposed on the substrate 110. The first semiconductor layer 120 may be formed of a compound semiconductor of groups III-V, group II-VI, or others. Furthermore, the first semiconductor layer 120 may include a nitride semiconductor layer such as (Al, Ga, In)N. For example, the first semiconductor layer 120 may include a GaN layer. In addition, the first semiconductor layer 120 may be a semiconductor layer doped with a first dopant. In this embodiment, the first dopant may be an n-type dopant. Therefore, the first semiconductor layer 120 may be an n-type semiconductor layer doped with an n-type dopant. For example, the n-type dopant may be Si, and a doping concentration may be about 1E17 atoms/cm³ to about 3E18 atoms/cm³. The first semiconductor layer 120 may be grown at about 800° C. to about 900° C.

The blocking layer 130 and the active layer 140 may be disposed on the first semiconductor layer 120. In addition, according to this embodiment, the blocking layer 130 and the active layer 140 may be formed in a structure including a groove-shaped approach region V₁.

The blocking layer 130 may be disposed on the first semiconductor layer 120 and function to prevent non-radiative carriers from diffusing into the active layer 140. For example, the blocking layer 130 may be disposed between the first semiconductor layer 120 and the active layer 140, thereby preventing a dopant used when the first semiconductor layer 120 is formed from diffusing and being injected into the active layer 140.

The blocking layer 130 may include a nitride semiconductor layer including indium. In addition, the blocking layer 130 may be formed in a structure in which a plurality of layers are stacked. The blocking layer 130 may include a first blocking layer 131 and a second blocking layer 132 having an indium composition ratio lower than that of the first blocking layer 131.

The first blocking layer 131 may have a highest indium content among the plurality of layers constituting the blocking layer 130. For example, the first blocking layer 131 may be an InGaN layer. In this case, the first blocking layer 131 may be formed so as to have the indium composition ratio of about 1% to about 10%. In addition, the first blocking layer 131 may be doped with an n-type dopant. For example, the dopant doped in the first blocking layer 131 may be Si, and a doping concentration may be about 1E17 atoms/cm³ to about 3E18 atoms/cm³.

In addition, the second blocking layer 132 may include a plurality of layers. Furthermore, the second blocking layer 132 may have a structure in which at least two layers having different band gap energies or different compositions are repeatedly stacked. For example, the second blocking layer 132 may have a structure in which a pair of layers including an InGaN layer and a GaN layer are repeatedly stacked.

According to an embodiment of the present invention, the blocking layer 130 may prevent the non-radiative carriers from being injected into the active layer 140, thereby preventing a decrease in a light-emitting efficiency in the active layer 140. That is, the blocking layer 130 may prevent a dopant from moving to the active layer 140, reducing non-radiative recombination therein and thus improving the light-emitting efficiency of the light emitting device 100.

In addition, according to an embodiment of the present invention, the blocking layer 130 may adjust a width and an area of the approach region V₁. In more detail, the blocking layer 130 may adjust a maximum width between inner sidewalls of the approach region V₁ and an area of the region between the inner sidewalls.

The active layer 140 may be disposed on the blocking layer 130. The active layer 140 may generate light through recombination of electrons and holes injected through the first semiconductor layer 120 and the second semiconductor layer 150.

The active layer 140 may be formed in any one of a single-well structure, a multi-well structure, a single quantum well structure, a multi quantum well (MQW) structure, a quantum dot structure, or a quantum wire structure.

The active layer 140 of the light emitting device 100 according to this embodiment may be a multi quantum well structure in which quantum well layers 141 and barrier layers 142 are alternately and repeatedly stacked. For example, the active layer 140 may include an active region formed of a pair of a quantum well layer 141 and a barrier layer 142, and the active regions may be stacked in multiple layers. Referring to FIGS. 1 and 2, a thickness of the active region may be about 10 nm to about 13.5 nm. The barrier layer 142 of the active region may be formed of a single layer or multiple layers.

The quantum well layer 141 may include a nitride semiconductor layer having an energy band gap narrower than that of the barrier layer 142. For example, the active layer 140 may include an InGaN layer. In addition, the barrier layer 142 may include a nitride semiconductor layer having a band gap wider than that of the quantum well layer 141. For example, the barrier layer 142 may be formed of at least one nitride semiconductor of GaN, InGaN, AlGaN, AlN, or AlInGaN. For example, the barrier layer 142 may include at least one layer of a GaN layer, an AlGaN layer, or an AlN layer.

A wavelength of light emitted from the active layer 140 may vary depending on a composition ratio of components forming the quantum well layer 141. The light emitting device 100 according to the embodiment of the present invention may emit light in the blue wavelength range since the quantum well layer 141 includes the InGaN layer and the barrier layer 142 includes the GaN or AlGaN layer.

In addition, the quantum well layer 141 and the barrier layer 142 of the active layer 140 may be formed as undoped layers that are not doped with dopants, thereby improving the crystalline quality of the active layer 140. However, the present invention is not limited thereto. The active layer 140 may be doped with a dopant in a partial region or in entire regions thereof so as to lower a forward voltage.

Light generated in the active layer 140 may be emitted to the outside of the semiconductor layer 115 through its side surface and upper surface. In addition, light generated in the active layer 140 may be emitted to the outside of the semiconductor layer 115 through the lower surface of the semiconductor layer 115.

Referring to FIGS. 1 and 2, each of the active layer 140 and the blocking layer 130 may include a flat region F and a slope region S as the approach region V₁ is formed. Herein, the slope region S serves as the approach region. In addition, a slope of the slope region S may constitute a s ide surface of the approach region V₁. Referring to FIG. 2, an inner side surface of the approach region V₁ corresponds to an upper surface of the active layer 140, and a space formed by the inner sidewalls of the approach region V₁ may be filled with the second semiconductor layer 150. In addition, an outer side surface of the approach region V₁ corresponds to a lower surface of the blocking layer 130, and may face the first semiconductor layer 120. In addition, in the slope region S (which corresponds to the approach region), slopes of respective layers may be upper surfaces or lower surfaces of the layers forming the active layer 140 and the blocking layer 130. In FIG. 1, one approach region V₁ in the blocking layer 130 and the active layer 140 is illustrated, but the inventive concepts are not limited thereto. A plurality of approach regions V₁ may be formed in the blocking layer 130 and the active layer 140.

According to this embodiment, the flat region F may include a first flat region F₁ positioned on one side of the slope region S and a second flat region F₂ positioned on the other side of the slope region S. In addition, the slope region S may include a first slope region S₁ and a second slope region S₂ which have inclination directions different from each other. The first slope region S₁ may be positioned between the first flat region F₁ and the second slope region S₂, and the second slope region S₂ may be positioned between the first slope region S₁ and the second flat region F₂. The first slope region S₁ has a downward inclination toward the second slope region S₂ from the first flat region F₁, and the second slope region S₂ has an upward inclination toward the second flat region F₂ from the first slope region S₁.

In addition, referring to FIG. 2, each of the layers including the approach region V₁ may have different thicknesses in the flat region F and in the slope region S. Furthermore, the thickness of the slope region S of each layer including the approach region V₁ may be smaller than the thickness of the flat region F. Therefore, a tunneling probability and movement speed of holes may be increased by the slope region S of a relatively thin barrier layer 142.

According to this embodiment, the quantum well layer 141 and the barrier layer 142 of the active layer 140 may each have a thickness in the slope region S that is smaller than the thickness in the flat region F, respectively. For example, a difference T_{FW}−T_{SW} between the thickness in the flat region F and the thickness in the slope region S of the quantum well layer 141 may be greater than about 2 nm and less than about 6 nm. When the thickness difference between the flat region F and the slope region S of the quantum well layer 141 is too small, a velocity deviation of electrons between the flat region F and the slope region S may decrease, thereby reducing a diffusion efficiency of electrons. In addition, when the thickness difference between the flat region F and the slope region S is too large, a region where the quantum well layer 141 is disconnected may occur. Therefore, when T_{FW}−T_{SW} is greater than about 2 nm and less than about 6 nm, the diffusion efficiency of electrons may be increased and the light emitting efficiency may be increased.

In addition, a difference T_{FB}−T_{SB} between the thickness of the flat region F and the thickness of the slope region S of the barrier layer 142 may be greater than about 0.5 nm and less than about 3 nm. In addition, (T_{FW}−T_{SW})/(T_{FB}−T_{SB}), which is a ratio of the thickness difference between the flat region F and the slope region S of the quantum well layer 141 to the thickness difference between the flat region F and the slope region S of the barrier layer 142 may be greater than about 0.08 and less than about 1.5. When the thickness difference between the flat region F and the slope region S of the barrier layer 142 is too small, a diffusion efficiency of holes may decrease. In addition, when the thickness difference between the flat region F and the slope region S of the barrier layer 142 is too large, a disconnection may occur between the flat region F and the slope region S of the barrier layer 142. Therefore, when (T_{FW}−T_{SW})/(T_{FB}−T_{SB}) is greater than about 0.08 and less than about 1.5, the diffusion efficiency of holes may be improved and a quality of a thin film may be improved.

In addition, a ratio (T_{SW}/T_{FW}) of the thickness of the slope region S to the thickness of the flat region in the quantum well layer 141 may be greater than about 0.25 and less than about 0.8. When the thickness ratio of the flat region F and the slope region S of the quantum well layer 141 is too small, a velocity deviation of electrons between the flat region F and the slope region S may decrease, thereby reducing a diffusion efficiency of electrons. In addition, when the thickness ratio of the flat region F and the slope region S is too large, a disconnection may occur between the flat region F and the slope region S of the quantum well layer 141. Therefore, when T_{SW}/T_{FW} is greater than about 0.25 and less than about 0.8, the diffusion efficiency of electrons may be increased and a light-emitting region may be sufficiently secured.

In addition, a ratio T_{SB}/T_{FB} of the thickness of the slope region S to the thickness of the flat region F in the barrier layer 142 may be greater than about 0.45 and less than about 0.78. When the thickness ratio of the flat region F and the slope region S of the barrier layer 142 is too small, a tunneling efficiency of holes in the flat region F may decrease. In addition, when the thickness ratio of the flat region F and the slope region S is too large, a disconnection may occur between the flat region F and the slope region S of the barrier layer 142. Therefore, when T_{SB}/T_{FB} is greater than about 0.45 and less than about 0.78, the diffusion efficiency of holes may be increased and the light-emitting region may be sufficiently secured.

In addition, (T_{SW}/T_{FW})−(T_{SB}/T_{FB}), which is a difference between the thickness ratio of the slope region S and the flat region F of the quantum well layer 141 and the thickness ratio of the slope region S and the flat region F of the barrier layer 142 may be greater than about −0.02 and less than about 0.2. In this case, a number of holes entering the quantum well layer 141 may be increased.

In addition, the quantum well layer 141 of the active layer 140 in each of the flat region F and the slope region S may have a thickness smaller than that of the barrier layer 142. For example, a ratio (T_{SW}/T_{SB}) of the thickness of the quantum well layer 141 to the thickness of the barrier layer 142 in the slope region S may be greater than about 0.14 and less than about 0.4. In addition, a ratio (T_{FW}/T_{FB}) of the thickness of the quantum well layer 141 to the thickness of the barrier layer 142 in the flat region F may be greater than about 0.22 and less than about 0.44. In addition, (T_{FW}/T_{FB})−(T_{SW}/T_{SB}), which is a difference between the ratio of the thickness of the quantum well layer 141 and the barrier layer 142 in the flat region F and the ratio of the thickness of the quantum well layer 141 and the barrier layer 142 in the slope region S may be greater than about 0.04 and less than about 0.3. Therefore, a probability that holes injected from the second semiconductor layer 150 reach the quantum well layer 141 positioned close to the first semiconductor layer 120 may be increased. In addition, it is possible to prevent electrons injected from the first semiconductor layer 120 from reaching the second semiconductor layer 150.

Respective layers forming the blocking layer 130 and the active layer 140 have a first slope 145 positioned on the first slope region S₁ and a second slope 146 positioned on the second slope region S₂ . In addition, the respective layers included in the blocking layer 130 and the active layer 140 has an intersection where the first slope 145 and the second slope 146 meet. In this embodiment, among the intersections of the approach region V₁ of the layers forming the blocking layer 130 and the active layer 140, an uppermost intersection is a first intersection N₁ and a lowermost intersection becomes a second intersection N₂. That is, the first intersection N₁ is positioned on the upper surface of the active layer 140 in the slope region S which is the approach region, and the second intersection N₂ is positioned on the lower surface of the blocking layer 130 in the slope region S. In addition, the second intersection N₂ may become a lower end of the approach region V₁.

Referring to FIG. 2, the approach region V₁ may have a symmetrical structure with respect to a virtual line L connecting the first intersection N₁ and the second intersection N₂ of this embodiment. In addition, points where the flat surfaces and the slopes of respective layers forming the blocking layer 130 and the active layer 140 meet may be positioned on the same line in each of both directions. Therefore, in the approach region V₁, an angle θ₁ of the first slope 145 and an angle θ₂ of the second slope 146 may be same with respect to the virtual line L. In addition, the approach region V₁ may have a structure in which both side regions are symmetrical and have a same area with respect to the virtual line L. Accordingly, both side regions of an inner region R of the approach region V₁ surrounded by the first slope 145 and the second slope 146 of the approach region V₁ may have a same area with respect to the virtual line L. Herein, the inner region R of the approach region V₁ is a region between the first slope 145 and the second slope 146 which are the inner surfaces of the approach region V₁. A region surrounded by the first slope 145 of the approach region V₁ and the virtual line L may be a first inner region R₁, and a region surrounded by the second slope 146 of the approach region V₁ and the virtual line L may become a second inner region R₂. For example, the first inner region R₁ and the second inner region R₂ may have a same area. However, the structure of the approach region V₁ of the light emitting device 100 of the present invention is not limited thereto. The approach region V₁ of the light emitting device 100 in the present invention may be asymmetrical in both regions, and the points where the flat surfaces and the slopes of the respective layers meet may not be positioned on the same line in each of both directions.

A region having a relatively high resistance and a high energy band gap may be formed on a side surface of the approach region V₁.

Light of a wavelength range targeted by the light emitting device 100 may be not generated in the approach region V₁ of the active layer 140. In addition, when a dopant flows into the active layer 140 of the slope region S which is the approach region, non-radiative recombination may occur due to the dopant, which may lower the light-emitting efficiency of the light emitting device 100. Therefore, the light emitting device 100 of this embodiment may prevent the dopant that induces non-radiative recombination from flowing into the approach region V₁ through the blocking layer 130 formed between the first semiconductor layer 120 and the active layer 140, thereby reducing the non-radiative recombination.

Referring to FIGS. 1 and 2, the second intersection N₂, which is the lower end of the approach region V₁, may be positioned in a partial region of the first semiconductor layer 120. That is, in this embodiment, the approach region V₁ may be formed to have a size such that the second intersection N_{2,} which is the lower end thereof, is positioned inside the first semiconductor layer 120.

According to an embodiment of the present invention, the size of the approach region V₁ may be adjusted by the blocking layer 130. That is, the approach region V₁ may be adjusted in width and area by the blocking layer 130. In more detail, by adjusting an indium content of the first blocking layer 131, a maximum separation distance between the inner surfaces of the approach region V₁ and the area of the inner region R of the approach region V₁ may be adjusted.

The light emitting device 100 according to an embodiment of the present invention, when the semiconductor layer 115 is formed on the substrate 110, may form a scattering line 160 by utilizing a difference between a lattice structure of the substrate 110 and a lattice structure of the semiconductor layer 115. The scattering line 160 may be formed in the first semiconductor layer 120 to pass through the superlattice layer and the active layer 140 and extend to the inner region R of the approach region V₁. Herein, the inner region R of the approach region V₁ is a region between the inner surfaces, and may be filled with the second semiconductor layer 150.

In the inner region R of the approach region V₁, the scattering line 160 may scatter light emitted from the active layer 140 in various directions. The active layer 140 may include the flat region F and the slope region S due to a groove structure. Since the flat region F and the slope region S have different inclination angles, angles of light emitted from each region are also different. In addition, the flat region F and the slope region S also have different angles with respect to the scattering line 160 positioned in the inner region R of the approach region V₁. Accordingly, a direction of propagation of light emitted from the flat region F of the active layer 140 and refracted in the scattering line 160 and a direction of propagation of light emitted from the slope region S of the active layer 140 and refracted in the scattering line 160 may be different from each other. Therefore, the light emitting device 100 of this embodiment may uniformly emit light in various directions by light emitted from the flat region F of the active layer 140 and light emitted from the slope region S, as well as light refracted from the scattering line 160.

In addition, according to this embodiment, the scattering line 160 does not extend only in one direction, and at least one region thereof may have a curved structure. Furthermore, the scattering line 160 may have a structure that is curved in various directions in a plurality of regions. Therefore, the scattering line 160 may have several angles with respect to the slope region S, and may also have several angles with respect to the flat region F. That is, the first slope 145 and the second slope 146 of the active layer 140 may have a plurality of inclination angles with respect to the scattering line 160. Accordingly, light emitted from the slope region S of the active layer 140 may also be refracted in various directions depending on a part where it hits the scattering line 160, and light emitted from the flat region F may also be refracted in various directions depending on a part where it hits the scattering line 160. Therefore, the light emitting device 100 of this embodiment may improve light uniformity by the scattering line 160 having a structure curved in various directions.

As the indium content of the first blocking layer 131 increases, the width between the inner surfaces of the approach region V₁ may increase, and accordingly, the area of the inner region R of the approach region V₁ may increase.

In a case that the approach region V₁ is small enough to have the second intersection N₂ positioned over the first semiconductor layer 120, the size of the approach region V₁ may be reduced, thereby reducing the area of the inner region R in which the scattering line 160 can be formed.

However, when the approach region V₁ is large enough to have the second intersection N₂ positioned in a partial region of the first semiconductor layer 120, the area of the inner region R in which the scattering line 160 can be formed may be increased. Therefore, the light emitting device 100 of this embodiment may secure a sufficient area for forming the scattering line 160 by a large-sized approach region V₁, and accordingly, the scattering line 160 may be more effectively formed.

FIG. 3 is a graph showing the compositional profiles of the first semiconductor layer 120, the blocking layer 130, and the active layer 140 of the light emitting device (100 in FIG. 1) according to the first embodiment. According to this embodiment, the blocking layer 130 includes the first blocking layer 131 and the second blocking layer 132, and the second blocking layer 132 is formed of three layers. This is only one example of the light emitting device 100 of the present invention, and the light emitting device 100 of the present invention is not limited thereto. The number of layers forming the first blocking layer 131 and the second blocking layer 132 of the blocking layer 130 may be varied.

Referring to FIG. 3, in the light emitting device 100 according to this embodiment, an indium content of each layer of the blocking layer 130 may be equal to or lower than that of the active layer 140, and may be higher than that of the first semiconductor layer 120. In addition, the first blocking layer 131 may have an indium content that is equal to or lower than that of the active layer 140, and higher than that of the second blocking layers 132. That is, the indium content of the first blocking layer 131 may be higher than that of the second blocking layer 132, and may be equal to or lower than that of the active layer 140.

According to an embodiment of the present invention, among the plurality of layers included in the blocking layer 130, the first blocking layer 131 closest to the first semiconductor layer 120 may have a relatively large indium content and thickness. Such a first blocking layer 131 may increase a maximum width of the approach region V₁ of the active layer 140, thereby effectively generating the scattering line 160.

The blocking layer 130 of the light emitting device 100 of this embodiment includes one first blocking layer 131 and three second blocking layers 132, without being limited thereto. A number of the second blocking layers 132 of the light emitting device 100 in this embodiment may be varied. In addition, the light emitting device 100 of this embodiment may not include the second blocking layer 132. That is, the blocking layer 130 of the light emitting device 100 in this embodiment may include only one or more first blocking layers 131.

The second semiconductor layer 150 may be disposed on the active layer 140. In addition, the second semiconductor layer 150 may fill the approach region V₁ of the active layer 140, and may be formed such that an upper surface thereof is generally flat.

The second semiconductor layer 150 may be formed of a compound semiconductor of group III-V, group II-VI, or others. Furthermore, the second semiconductor layer 150 may include a nitride semiconductor layer such as (Al, Ga, In)N. For example, the second semiconductor layer 150 may include a GaN layer. In addition, the second semiconductor layer 150 may be a semiconductor layer doped with a second dopant. The second semiconductor layer 150 in this embodiment may be a p-type semiconductor layer doped with a p-type dopant. For example, the p-type dopant may be Mg.

A type of light generated from the light emitting device 100 may vary depending on the types of compositions forming the first semiconductor layer 120, the second semiconductor layer 150, and the active layer 140. The light emitting device 100 according to this embodiment may emit blue light.

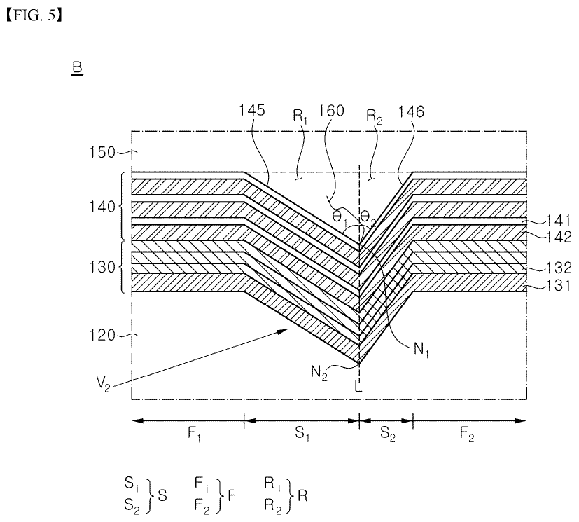

FIGS. 4 and 5 are diagrams illustrating a light emitting device according to a second embodiment of the present invention. FIG. 4 is a cross-sectional view schematically illustrating one region of the light emitting device according to the second embodiment of the present invention. In addition, FIG. 5 is an enlarged view of region B of FIG. 4.

A light emitting device 200 according to the second embodiment of the present invention has configurations the same as those of the light emitting device of the previous embodiment (100 in FIG. 1) except for a structure of an approach region V₂. Therefore, for detailed descriptions of components other than the approach region V₂ of the light emitting device 200 according to the second embodiment, refer to the description of the light emitting device 100 of FIG. 1 of the previous embodiment.

The light emitting device 200 according to this embodiment may include a substrate 110 and a semiconductor layer 115. In addition, the semiconductor layer 115 may include a first semiconductor layer 120, a blocking layer 130, an active layer 140, and a second semiconductor layer 150. In addition, the blocking layer 130 and the active layer 140 may be formed in a structure including the approach region V₂.

Referring to FIGS. 4 and 5, the approach region V₂ may be formed in a structure with asymmetrical sides. Referring to FIG. 5, the approach region V₂ may include a first intersection N₁, which is a portion where both side surfaces of the approach region V₂ meet on an upper surface of the active layer 140, and a second intersection N₂, which is a portion where both side surfaces of the approach region V₂ meet on a lower surface of the blocking layer 130. The approach region V₂ may be divided into a first slope S₁ as one region and a second slope S₂ as the other region with respect to a virtual line L connecting the first intersection N₁ and the second intersection N₂.

In the light emitting device 200 according to this embodiment, a first slope 145 of the first slope region S₁ and a second slope 146 of the second slope region S₂ may have different angles with respect to the virtual line L. In addition, the first slope region S₁ and the second slope region ₂S of the approach region V₂ may have different areas. Accordingly, a first inner region R₁ and a second inner region R₂ surrounded by the approach region V₂ may have different areas. According to this embodiment, an angle θ₁ of the first slope 145 may be greater than an angle θ₂ of the second slope 146 with respect to the virtual line L. In addition, an area of the first slope region S₁ may be larger than that of the second slope region S₂. In addition, an area of the first inner region R₁ may be larger than that of the second inner region R₂. For example, the area of the first inner region R₁ may exceed the area of the second inner region R₂ and may be 1.4 times or less of the area of the second inner region R₂. Conversely, in the approach region V₂ of the light emitting device 200, the angle θ₂ of the second slope 146 may be greater than the angle θ₁ of the first slope 145 with respect to the virtual line L. In addition, the area of the second slope region S₂ may be larger than that of the first slope region S₁. In addition, the area of the second inner region R₂ may be larger than that of the first inner region R₁. For example, the area of the second inner region R₂ may exceed the area of the first inner region R₁ and may be 1.4 times or less of the area of the first inner region R₁.

According to an embodiment of the present invention, an inner region R of the approach region V₂ has one region and the other region that have areas different form each other with respect to the virtual line L. Accordingly, a scattering line 160 may be formed with a relatively longer length in a wider region among one region and the other region of the inner region R of the approach region V₂. For example, a formation of the scattering line 160 may be performed more in the first inner region R₁ having a relatively wider area among the first inner region R₁ and the second inner region R₂ of the approach region V₂. In addition, since the area of the first inner region R₁ is larger than that of the second inner region R₂. the scattering line 160 may be positioned such that a longer portion of the total length of the scattering line 160 is located in the first inner region R₁. That is, a length of the scattering line 160 formed in the first inner region R₁ having a relatively larger area may be longer than that of the scattering line 160 formed in the second inner region R₂ having a relatively smaller area. Accordingly, the scattering line 160 may be formed longer than when the approach region V₂ is a symmetrical structure with respect to the virtual line L. In addition, as the length of the scattering line 160 increases, the scattering line 160 may be formed to have more various angles with respect to an inner surface of the approach region V₂, thereby improving light extraction efficiency.

Therefore, in the light emitting device 200 of this embodiment, a light scattering effect by the scattering line 160 may be further improved due to the structure of the inner region R of the approach region V₂ described above, and light uniformity may be improved.

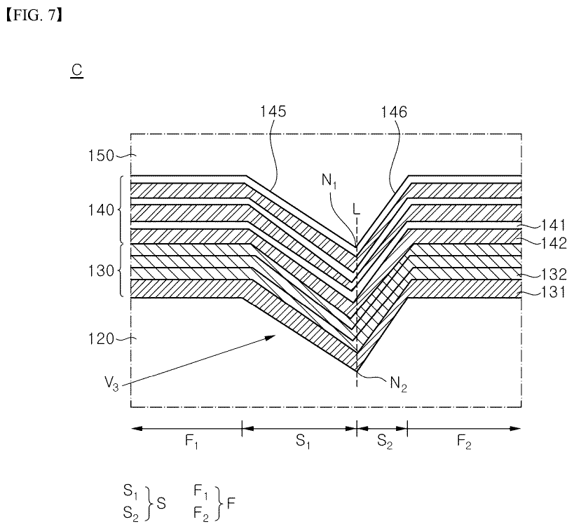

FIG. 6 and FIG. 7 are diagrams illustrating a light emitting device according to a third embodiment of the present invention. FIG. 6 is a cross-sectional view schematically illustrating one region of the light emitting device according to the third embodiment of the present invention. In addition, FIG. 7 is an enlarged view of region C of FIG. 6.

A light emitting device 300 according to the third embodiment of the present invention has configurations the same as those of the light emitting devices of the previous embodiments (100 in FIG. 1 and 200 in FIG. 4) except for a structure of an approach region V₃. Therefore, for detailed descriptions of components other than the approach region V₃ of the light emitting device 300 according to the third embodiment, refer to the descriptions of the light emitting devices of the previous embodiments (100 in FIG. 1 and 200 in FIG. 4).

The light emitting device 300 according to this embodiment may include a substrate 110 and a semiconductor layer 115. In addition, the semiconductor layer 115 may include a first semiconductor layer 120, a blocking layer 130, an active layer 140, and a second semiconductor layer 150. In addition, the blocking layer 130 and the active layer 140 may be formed in a structure including the approach region V₃.

Referring to FIGS. 6 and 7, the approach region V₃ of this embodiment may be formed in a structure with asymmetrical sides like the approach region V₂ of the light emitting device 200 of the second embodiment of FIGS. 4 and 5.

In the approach region V₃ of this embodiment, an intersection of at least one layer among a plurality of layers forming the approach region V₃ may be positioned outside a virtual straight line L connecting a first intersection N₁ and a second intersection N₂. Furthermore, in the light emitting device 300 according to this embodiment, intersections of respective layers forming the approach region V₃ may be irregularly positioned as shown in FIG. 7.

That is, the approach region V₃ may include slopes facing each other for each layer, and may include intersections where the slopes facing each other meet. In addition, the intersections may include the first intersection N₁ that is positioned farthest from the first semiconductor layer 120 and the second intersection N₂ that is positioned closest to the first semiconductor layer 120. In addition, a straight line L passing through the first intersection N₁ and the second intersection N₂ may be spaced apart from intersections disposed between the first intersection N₁ and the second intersection N₂.

In addition, a position of a boundary point between a flat region F and a slope region S of at least one layer among the plurality of layers forming the approach region V₃ may be different from those of other layers. Furthermore, boundary points of the flat region F and the slope region S of respective layers forming the blocking layer 130 and the active layer 140 may not be positioned on a single line but may be positioned irregularly as shown in FIG. 7. In addition, since the boundary points of the respective layers forming the blocking layer 130 and the active layer 140 are irregularly positioned, at least one of slopes may have a different length. Furthermore, slopes of the respective layers forming the blocking layer 130 and the active layer 140 may have different lengths. Accordingly, the light emitting device 300 of this embodiment is provided with a plurality of layers having different angles of slopes, and thus, an angle of refraction of light passing through the active layer 130 and the blocking layer 130 may be varied, and a range of refraction angles may be widened. Therefore, the light emitting device 300 of this embodiment may emit a large amount of light to the outside at various angles.

FIG. 8 is a cross-sectional view schematically illustrating one region of a light emitting device according to a fourth embodiment of the present invention.

Referring to FIG. 8, a light emitting device 400 according to the fourth embodiment of the present invention may include a substrate 110 and a semiconductor layer 415. In addition, the semiconductor layer 415 may include a first buffer layer 460, a first semiconductor layer 120, a blocking layer 130, an active layer 440, and a second semiconductor layer 150. In addition, the blocking layer 130 and the active layer 440 may be formed in a structure including an approach region V.

The light emitting device 400 according to the fourth embodiment of the present invention has configurations the same as those of the light emitting devices (100 of FIG. 1, 200 of FIG. 4, and 300 of FIG. 6) of the previous embodiments except for the first buffer layer 460 and the active layer 440. Therefore, a description of the light emitting device 400 according to the fourth embodiment will be mainly described in terms of the differences from the light emitting devices (100 in FIG. 1, 200 in FIG. 4, and 300 in FIG. 6) of the previous embodiments. For detailed descriptions of omitted components, refer to the descriptions of the light emitting devices (100 in FIG. 1, 200 in FIG. 4, and 300 in FIG. 6) of the previous embodiments.

According to an embodiment of the present invention, the first buffer layer 460 may be disposed between the substrate 110 and the first semiconductor layer 120. The first buffer layer 460 may alleviate stress and strain due to differences in the lattice constant and the thermal expansion coefficient between the substrate 110 and the first semiconductor layer 120. Therefore, the occurrences of cracks, warpage, and generation of dislocations within the first semiconductor layer 120 may be prevented and minimized by the first buffer layer 460. For example, the first buffer layer 460 may be formed of undoped GaN.

According to an embodiment of the present invention, the active layer 440 may include a quantum well layer 141, a barrier layer 142, and a second buffer layer 470. Referring to FIG. 8, the second buffer layer 470 may be disposed between the quantum well layer 141 and the barrier layer 142. The second buffer layer 470 may be formed by including aluminum (Al) to alleviate stress and strain caused by differences in lattice constant and thermal expansion coefficient between the quantum well layer 141 and the barrier layer 142. Therefore, the second buffer layer 470 may prevent cracks and distortion within the active layer 440. The active layer 440 may have a structure in which an active region formed of a pair of the quantum well layer 141 and barrier layer 142 is stacked in a plurality of layers. In this case, the second buffer layer 470 may be formed between the quantum well layer 141 and the barrier layer 142 of at least one active region among a plurality of active regions. Alternatively, the second buffer layer 470 may be formed between the quantum well layer 141 and the barrier layer 142 for each active region.

According to an embodiment of the present invention, the second buffer layer 470 may include a second-1 buffer layer 471 and a second-2 buffer layer 472. The second-1 buffer layer 471 may be disposed on the quantum well layer 141, and the second-2 buffer layer 472 may be disposed on the second-1 buffer layer 471. For example, the second-1 buffer layer 471 may be formed of AIN, and the second-2 buffer layer 472 may be formed of AlGaN.

In addition, the second-1 buffer layer 471 may be formed thinner than the second-2 buffer layer 472. For example, the second-1 buffer layer 471 may be formed with a thickness of about 1 nm or less, and the second-2 buffer layer 472 may be formed with a thickness of about 1 nm to about 2 nm. In addition, the second-1 buffer layer 471 may be omitted in the second buffer layer 470 and only the second-2 buffer layer 472 may be included.

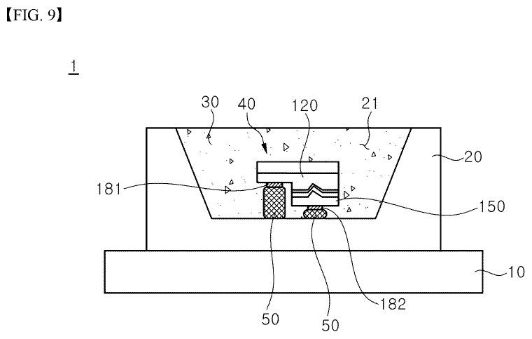

FIG. 9 is a schematic cross-sectional view of a light emitting package according to an embodiment of the present invention.

Referring to FIG. 9, a light emitting package 1 may include a circuit board 10, a housing 20, a light-transmitting resin, and a light emitting device 40. The light emitting device 40 may be any one of the light emitting devices 100, 200, 300, and 400 according to the first to fourth embodiments described above.

The circuit board 10 supports the housing 20 in which the light emitting device 40 is mounted, and may supply voltage and current applied from the outside to the light emitting device 40.

Although not shown in FIG. 9, the circuit board 10 may include a base and a plurality of conductive patterns spaced apart from one another. The base may be formed of an insulation material. For example, it may be formed of at least one material selected from a group consisting of phenol, epoxy, polyimide, and ceramic. Alternatively, the base may include a metallic layer and an insulation layer formed on a surface of the metallic layer. For example, the insulation layer may be an insulating resin or an oxide. That is, the base may be formed of an insulation material or may be formed in a structure that can be insulated from the conductive pattern. The conductive pattern may be formed over and under the base. In addition, the conductive pattern may be further formed on an interior or side surface of the base so as to electrically connect the conductive pattern formed over the base with the conductive pattern formed under the base. The conductive pattern may be formed of any material that is conductive. For example, the conductive pattern may be formed of metal. The circuit board 10 like this may supply voltage and current applied from the outside to the light emitting device 40 through the conductive pattern.

The housing 20 may be formed of an insulation material. For example, the housing 20 may be formed by including at least one material among ceramic resin, silicone resin, epoxy resin, polyimide resin, and urethane resin.

In addition, the housing 20 may be formed with a cavity 21 formed to have a predetermined depth from an upper surface toward a lower surface thereof. The light emitting device 40 may be disposed in the cavity 21 of the housing 20. In addition, an inner side surface of the housing 20 forming the cavity 21 may be formed to have an inclination so as to reflect light emitted from the light emitting device 40 in an upward direction.

Although not shown in FIG. 9, the housing 20 may include a plurality of conductive patterns. The conductive pattern of the housing 20 may be exposed in the cavity 21, and may be exposed through at least one surface among a side surface or lower surface of the housing 20. In addition, a conductive pattern exposed in the cavity 21 and a conductive pattern exposed on the surface of the housing 20 may be electrically connected to each other.

The light emitting device 40 disposed in the cavity 21 of the housing 20 may be one type of the light emitting devices 100, 200, 300, and 400 described through FIGS. 1 through 8. In this case, the light emitting device 40 may include a first electrode 181 electrically connected to a first semiconductor layer 120 and a second electrode 182 electrically connected to a second semiconductor layer 150.

When the light emitting device 40 is disposed in the cavity 21 of the housing 20, the first electrode 181 and the second electrode 182 of the light emitting device 40 may be exposed in the cavity 21 and may be electrically connected to the conductive patterns that are spaced apart from each other, respectively. The first electrode 181 and the second electrode 182 of the light emitting device 40 may be electrically connected to the conductive patterns through a conductive material such as a bump 50. In this case, the light emitting device 40 may be fixed in the cavity 21 of the housing 20 by the conductive material.

Referring to FIG. 9, the light emitting device 40 of this embodiment has a lateral type structure in which the first electrode 181 and the second electrode 182 are disposed in the same direction. However, the structure of the light emitting device 40 applied to the light emitting package 1 of the present invention is not limited thereto. As another example, the light emitting device 40 may have a vertical type structure in which the first electrode 181 and the second electrode 182 are disposed in different directions. As another example, the light emitting device 40 may have a structure in which the first electrode 181 and the second electrode 182 are disposed in a same direction, and an upper surface or lower surface of the first electrode 181 and the second electrode 182 are positioned at a same height.

As such, the light emitting device 40 of various structures may be applied to the light emitting package 1 of the present invention, and a method of electrically connecting the conductive patterns of the housing 20 may also be changed in various ways depending on the structure of the light emitting device 40. As another example, both the first electrode 181 and the second electrode 182 of the light emitting device 40 may be electrically connected to the conductive patterns of the housing 20 via wires. As another example, in the light emitting device 40, one of the first electrode 181 and the second electrode 182 may be electrically connected by contacting the conductive patterns of the housing 20, and the other electrode may be electrically connected to the conductive patterns of the housing 20 through the wires.

A light transmitting layer 30 may be formed in the cavity 21 of the housing 20 so as to cover the light emitting device 40. The light transmitting layer 30 may cover the light emitting device 40 to secure the light emitting device 40 to the cavity 21 of the housing 20, and may protect it from external materials or external impact.

The light transmitting layer 30 may be formed of a material through which light emitted from the light emitting device 40 is transmitted. For example, the light transmitting layer 30 may be formed by including at least one material among polymer resin, glass, or ceramic. In addition, the light transmitting layer 30 may further include materials, such as wavelength conversion materials, scattering materials, reflective materials, or others, which can convert a wavelength of light or change a direction of light propagation in various ways.

In addition, in FIG. 9, the light transmitting layer 30 has a structure with a flat upper surface. However, the structure of the light transmitting layer 30 is not limited thereto. As another example, the light transmitting layer 30 may be formed such that at least a portion of the upper surface includes a convex curved surface or a concave curved surface. As such, the light transmitting layer 30 may be formed into various structures so as to adjust a viewing angle or the direction of light propagation of the light emitting package 1.

The light emitting devices 100, 200, 300, and 400 according to embodiments of the present invention may be applied not only to the light emitting package 1, but also to various light emitting modules such as lighting, automotive lamps, and display devices.

As described above, although the detailed descriptions of the present invention have been made by the embodiments with reference to the accompanying drawings, the above-described embodiments have only been described by using preferred examples of the present invention, and the scope of the present invention should not be understood as being limited to the embodiments, and should be understood by the claims described below and their equivalent concepts.

### DESCRIPTION OF REFERENCE NUMERALS

1: Light emitting package
10: Circuit board
20: Housing
21: Cavity of housing
30: Light transmitting layer
50: Bump
100, 200, 300, 400: Light emitting device
110: Substrate
115: Semiconductor layer
120: First semiconductor layer
130: Blocking layer
131: First blocking layer
132: Second blocking layer
140: Active layer
141: Quantum well layer
142: Barrier layer
145: First slope
146: Second slope
150: Second semiconductor layer
160: Scattering line
181: First electrode
182: Second electrode
460: First buffer layer
470: Second buffer layer
471: Second-1 buffer layer
472: Second-2 buffer layer
F: Flat region
F₁: First flat region
F₂: Second flat region
R: Inner region of approach region
R₁: First inner region of approach region
R₂: Second inner region of approach region
S: Slope region
S₁: First slope region
S₂: Second slope region
V, V1, V2, V3: Approach region

1. A light emitting device, comprising:
a first semiconductor layer doped with a first dopant;
a blocking layer disposed on the first semiconductor layer, and including indium;
an active layer disposed on the blocking layer; and
a second semiconductor layer disposed on the active layer, and doped with a second dopant, wherein:
the blocking layer and the active layer include a flat region and an approach region,
the approach region includes a slope region,
the approach region includes first slopes and second slopes facing each other, and includes intersections where the first slopes and the second slopes meet,
the intersections include a first intersection that is disposed farthest from the first semiconductor layer and a second intersection that is disposed closest to the first semiconductor layer, and
a straight line passing through the first intersection and the second intersection is spaced apart from intersections disposed between the first intersection and the second intersection.

2. The light emitting device of claim 1, wherein the straight line passing through the first intersection and the second intersection is inclined with respect to the flat region.

3. The light emitting device of claim 1, wherein a lower end of the approach region is positioned in a partial region of the first semiconductor layer.

4. The light emitting device of claim 1, wherein an indium content of the blocking layer is equal to or lower than that of the active layer, and higher than that of the first semiconductor layer.

5. The light emitting device of claim 4, wherein the blocking layer includes a first blocking layer disposed on the first semiconductor layer and a second blocking layer disposed on the first blocking layer.

6. The light emitting device of claim 5, wherein the blocking layer includes a plurality of the second blocking layers.

7. The light emitting device of claim 5, wherein an indium content of the first blocking layer is equal to or lower than that of the active layer, and an indium content of the second blocking layer is lower than that of the first blocking layer.

8. The light emitting device of claim 1, wherein a region between the first slope and the second slope forming the first intersection is symmetrical on both sides with respect to the straight line passing through the first intersection and the second intersection.

9. The light emitting device of claim 1, wherein the region between the first slope and the second slope forming the first intersection is asymmetrical on both sides with respect to the straight line passing through the first intersection and the second intersection.

10. The light emitting device of claim 1, wherein one of the first dopant and the second dopant is an n-type dopant, and the other dopant is a p-type dopant.

11. A light emitting device, comprising:
a first semiconductor layer doped with a first dopant;
a blocking layer disposed on the first semiconductor layer, and including indium;
an active layer disposed on the blocking layer; and
a second semiconductor layer disposed on the active layer, and doped with a second dopant, wherein:
the blocking layer and the active layer include an approach region having slope surfaces and a flat region,
the approach region includes first slopes and the second slopes facing each other, and
a scattering line is formed in an inner region which is a region between the first slopes and second slopes.

12. The light emitting device of claim 11, wherein the scattering line has a structure in which at least one region is curved.

13. The light emitting device of claim 12, wherein the first slope and the second slope of the active layer have a plurality of inclination angles with respect to the scattering line.

14. The light emitting device of claim 11, wherein a maximum separation distance between the first slopes and the second slopes of the approach region varies along a thickness direction.

15. The light emitting device of claim 14, wherein an indium content of the blocking layer is equal to or lower than that of the active layer, and higher than that of the first semiconductor layer.

16. The light emitting device of claim 15, wherein the blocking layer comprises a first blocking layer disposed on the first semiconductor layer and a second blocking layer disposed on the first blocking layer.

17. The light emitting device of claim 16, wherein an indium content of the first blocking layer is equal to or lower than that of the active layer, and an indium content of the second blocking layer is lower than that of the first blocking layer.

18. The light emitting device of claim 11, wherein:
the intersections comprise a first intersection that is disposed farthest from the first semiconductor layer and a second intersection that is disposed closest to the first semiconductor layer, and
a region between the first slope and the second slope forming the first intersection includes a first inner region formed on one side and a second inner region formed on the opposite side, which are asymmetrical with respect to a straight line passing through the first intersection and the second intersection.

19. The light emitting device of claim 18, wherein a longer portion of a total length of the scattering line is located in a wider one of the first inner region and the second inner region.
